(19) United States
(12) Patent Application Publication
(10) Pub. No.: US 2025/0174465 A1
(43) Pub. Date: May 29, 2025

(54) HARD MASK, SUBSTRATE PROCESSING METHOD, AND REMOVAL METHOD FOR HARD MASK

(71) Applicant: Tokyo Electron Limited, Tokyo (JP)

(72) Inventors: Xiaolong LI, Yamanashi (JP); Hiroki MAEHARA, Tokyo (JP); Shota ISHIBASHI, Yamanashi (JP); Toru KITADA, Yamanashi (JP)

(21) Appl. No.: 18/842,620

(22) PCT Filed: Feb. 15, 2023
(86) PCT No.: PCT/JP2023/005159

§ 371 Date: Aug. 29, 2024

(30) Foreign Application Priority Data
Mar. 1, 2022 (JP) 2022-031091

(51) Int. Cl. H01L 21/311; H01L 21/033; H10B 12/00

(52) U.S. Cl. CPC H01L 21/31144; H01L 21/0332; H01L 21/0337; H01L 21/31116; H10B 12/03

(57) ABSTRACT

A hard mask used for etching a processing target includes an oxide containing one or more of gallium, indium, and zinc. The hard mask that includes the oxide containing one or more of gallium, indium, and zinc is formed on a substrate having the processing target, and is etched into a desired pattern, and the processing target is etched using the hard mask as a mask.

### TECHNICAL FIELD

The present disclosure relates to a hard mask, a substrate processing method, and a method of removing the hard mask.

### BACKGROUND

In the manufacturing process of semiconductor devices, there is a step of processing a predetermined film, such as Si-containing film, into, e.g., trenches or holes by plasma etching. Although a resist mask has conventionally been used as a mask for etching, the etching resistance of the resist mask alone has become insufficient due to pattern miniaturization, leading to the use of a hard mask.

Patent Document 1 describes combinations of SiN films, SiO₂ films, SiON films, SiC films, amorphous Si films (a-Si films), and TiN films as a hard mask. On the other hand, Patent Document 2 describes the use of a-Si films or amorphous carbon films (a-C films) as a hard mask that is used when forming recesses such as trenches in SiO₂ films. Further, Patent Document 3 describes the use of films containing tungsten and films containing zirconium or titanium and oxygen as a hard mask when etching silicon-containing films.

### PRIOR ART DOCUMENTS

### Patent Documents

Patent Document 1: Japanese laid-open publication No. 2003-037162
Patent Document 2: Japanese laid-open publication No. 2013-179218
Patent Document 3: Japanese laid-open publication No. 2021-141260

The present disclosure provides a hard mask having a high selectivity with respect to a processing target so that it can be made as a thinner film, a substrate processing method, and a method of removing the hard mask.

### SUMMARY

According to one embodiment of the present disclosure, there is provided a hard mask used for etching of a processing target, the hard mask including an oxide containing one or more of gallium, indium, and zinc.

According to the present disclosure, it is possible to provide a hard mask having a high selectivity with respect to a processing target so that it can be made as a thinner film, a substrate processing method, and a method of removing the hard mask.

### BRIEF DESCRIPTION OF DRAWINGS

FIG. 1 is a flowchart illustrating a substrate processing method including a series of steps for etching a processing target using a hard mask according to an embodiment.

FIG. 2 is a diagram illustrating an example of a substrate in step ST1 of the substrate processing method of FIG. 1.

FIG. 3 is a diagram illustrating an example of a state in step ST2 of the substrate processing method of FIG. 1.

FIG. 4 is a diagram illustrating an example of a state in step ST3 of the substrate processing method of FIG. 1.

FIG. 5 is a diagram illustrating an example of a state in step ST4 of the substrate processing method of FIG. 1.

FIG. 6 is a diagram illustrating an example of a state in step ST5 of the substrate processing method of FIG. 1.

FIG. 7 is a diagram illustrating an example of a state in step ST6 of the substrate processing method of FIG. 1.

FIGS. 8A and 8B are diagrams illustrating a method of removing a hard mask by reforming process and pure water cleaning.

FIG. 9 is a cross-sectional view illustrating an example of a film forming apparatus used for forming a hard mask.

FIG. 10 is a cross-sectional view illustrating an example of a plasma etching apparatus used for etching a hard mask and a processing target.

FIG. 11 is a diagram illustrating results of Experimental Example 1.

FIG. 12 is a diagram illustrating results of Experimental Example 2.

### DETAILED DESCRIPTION

Hereinafter, embodiments will be described in detail with reference to the accompanying drawings.

### Circumstances and Overview

First, circumstances and overview will be described.

In the manufacturing process of semiconductor devices, miniaturization has progressed, increasing the number of high aspect-ratio etching steps. Particularly in DRAM capacitors and 3DNAND, extremely high aspect-ratio etching is required. For example, DRAM capacitors require processing with an aspect ratio of 50 or more, where a critical dimension (CD) is 20 nm or less and a depth is 1.0 μm or more.

In a high aspect-ratio etching step, the etching rate of a processing target tends to decrease and the consumption of a hard mask increases, necessitating the formation of a thicker hard mask. However, increasing the film thickness of the hard mask ultimately deteriorates the roughness of an opening in the processing target. Conventionally, as hard masks that can achieve a relatively high selectivity, an amorphous silicon film, poly-Si film, amorphous carbon film, TiN film, and tungsten-containing film (e.g., WSi film), have been used, but there has been a demand for a hard mask having an even higher selectivity so that it can be made as a thinner film.

The inventors investigated a hard mask that can have a high selectivity and can be made as a thinner film. As a result, they found that it is effective to use an oxide containing one or more of gallium (Ga), indium (In), and zinc (Zn) as a hard mask.

An example of a processing method using such a hard mask includes preparing a substrate where a processing target is formed on a base, forming, on the processing target, a hard mask including an oxide that contains one or more of Ga, In, and Zn, etching the hard mask into a desired pattern, and etching the processing target using the etched hard mask. This processing method allows for the use of a thin hard mask, preventing deterioration in roughness at an opening of the processing target.

### Specific Embodiments

Hereinafter, specific embodiments will be described.

Here, a substrate processing method including a series of steps for etching a processing target using a hard mask according to an embodiment will be described.

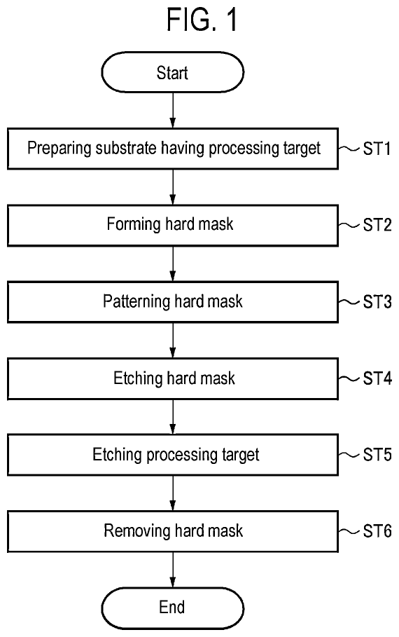

FIG. 1 is a flowchart illustrating such a substrate processing method. As illustrated in FIG. 1, this method includes preparing a substrate having a processing target (step ST1), forming a hard mask on the processing target (step ST2), patterning the hard mask (step ST3), etching the hard mask (step ST4), etching the processing target (step ST5), and removing the hard mask (step ST6).

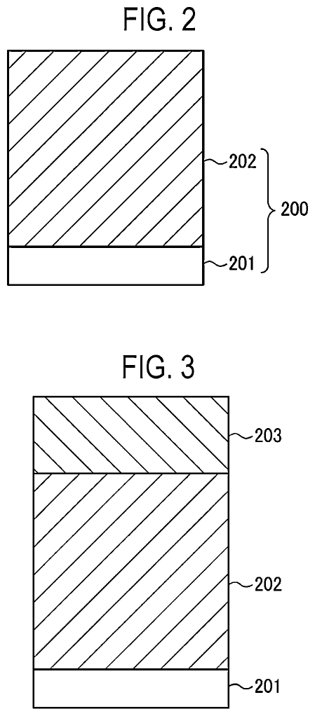

As illustrated in FIG. 2, a substrate 200 where a processing target 202 to be etched is formed on a base 201 is exemplified as the substrate in step ST1. The substrate may have an underlying film of the processing target 202 on the base 201. The substrate 200 is not particularly limited, and may be, for example, a semiconductor wafer having a semiconductor base such as silicon. The processing target 202 is not particularly limited, but a Si-containing film such as silicon (Si), silicon oxide (SiO₂), silicon nitride (SiN), silicon oxycarbonitride (SiOCN), or silicon oxynitride (SiON) is exemplified as a suitable example. Si may be any of monocrystalline Si, polycrystalline Si (poly-Si), and amorphous Si. For example, the processing target is a SiO₂ film if a target device is a DRAM capacitor, or is a stack of SiO₂ and SiN films if a target device is a 3DNAND.

In step ST2, as illustrated in FIG. 3, a hard mask 203 according to an embodiment is formed on the processing target 202 of FIG. 2. The hard mask 203 includes an oxide (IGZO-based film) containing one or more of Ga, In, and Zn. The hard mask 203 according to the present embodiment may be entirely or partially composed of such an oxide.

The hard mask 203 allows an etching of the processing target 202 with a high selectivity. Therefore, it can be made as a thinner film, and deterioration in roughness at an opening of the processing target is prevented. In particular, when the processing target 202 is a Si-containing film, the hard mask can etch the processing target 202 with a high selectivity, so that it can be thinner.

Further, the hard mask 203 is capable of etching the processing target 202 with a high selectivity when using a fluorine (F)-containing gas such as fluorocarbon (CₓF_{y}) gas, fluorinated hydrocarbon (CₓH_{y}F_{z}) gas, or sulfur hexafluoride (SF₆) gas as an etching gas for etching the processing target 202. In particular, the hard mask 203 exhibits significant effectiveness if the processing target 202 is a Si-containing film and a F-containing gas is used to etch the processing target 202.

The hard mask 203 may be amorphous without grain boundaries from the viewpoint of improving shape retention during etching. A method of forming the hard mask 203 is not particularly limited and may employ general thin-film forming techniques such as physical vapor deposition (PVD), chemical vapor deposition (CVD), and atomic layer deposition (ALD), and coating (spin coating). PVD such as sputtering may be suitably used from the viewpoint of obtaining an amorphous hard mask.

Examples of the oxide (IGZO-based film) containing one or more of Ga, In, and Zn that constitutes the hard mask 203 may include InGaZnO₄, In₂ZnO₄, Ga₂ZnO₄, In₂O₃, and ZnO. These have higher selectivities to the processing target, particularly to the Si-containing film, compared to conventional hard masks such as a-Si film, poly-Si film, a-C film, TiN film, and WSi film. Among these, ZnO achieves a high selectivity, but is easily crystallized at room temperature even when formed by PVD, thus being not readily become amorphous. On the other hand, InGaZnO₄, In₂ZnO₄, Ga₂ZnO₄, and In₂O₃ are more likely to become amorphous and may easily form an amorphous film by PVD. Accordingly, they are more desirable.

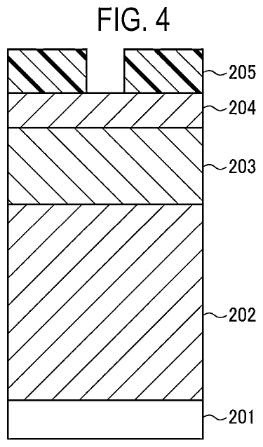

The patterning of the hard mask in step ST3 may be performed using, for example, photolithography techniques. Specifically, as illustrated in FIG. 4, after sequentially forming an anti-reflection film 204 and a photoresist film 205 on the hard mask 203, patterning is performed by exposure and development. At this time, the thickness of the photoresist film 205 is adjusted according to the thickness of the hard mask 203. When performing high selectivity processing, a high selectivity film may be added between the anti-reflection film 204 and the hard mask 203.

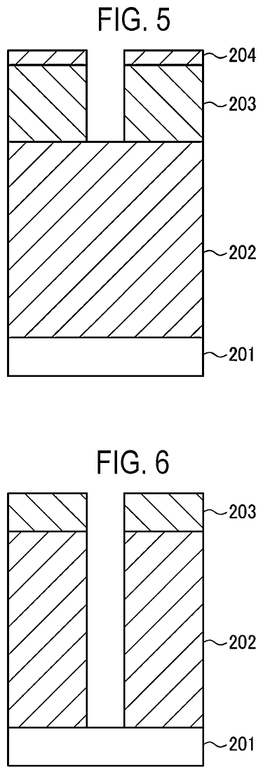

In step ST4, the hard mask is etched using a pattern formed in step ST3. Specifically, as illustrated in FIG. 5, the hard mask 203 is etched by anisotropic etching using a plasma, with the photoresist film 205 serving as a mask.

For etching the hard mask 203 composed of an IGZO-based film, an etching gas such as HBr gas, Cl₂ gas, CH₄ gas, CH₃OH gas, or BCl₃ gas may be used.

When using a HBr gas or Cl₂ gas as the etching gas, halogen-based residues are likely to remain, so that etching at a high temperature of about 120 degrees C. may be performed, followed by ashing. Further, in this case, it may be possible to add one or more of an O₂ gas, Ar gas, and N₂ gas to the HBr or Cl₂ gas.

When using a CH₄ gas, CH₃OH gas, or BCl₃ as the etching gas, low-temperature processing is possible. In this case, it may be possible to add a H₂ gas and Cl₂ gas to the CH₄, CH₃OH, or BCl₃ gas.

In step ST5, the processing target is etched using the hard mask etched in step ST4. Specifically, as illustrated in FIG. 6, the processing target 202 is etched by anisotropic etching using a plasma, with the etched hard mask 203 serving as a mask.

An etching gas used in step ST5 is not particularly limited, but a F-containing gas such as CₓF_{y} gas, CₓH_{y}F_{z} gas, or SF₆ described above may be suitably used. It may be possible to add, e.g., an O₂ gas, N₂ gas, and Ar gas to the F-containing gas.

The F-containing gas may be suitably used as the etching gas when the processing target 202 is a Si-based film as described above. Further, the IGZO-based film constituting the hard mask 203 has high resistance to such a F-containing gas. Further, fluorides of In, Ga, and Zn have high melting and boiling points, so that the hard mask 203 composed of these elements has basically high etching resistance to the F-containing gas even at high temperatures. However, as the temperature is lower, it becomes more difficult to etch the hard mask 203. Accordingly, in consideration of selectivity, a lower temperature is preferable.

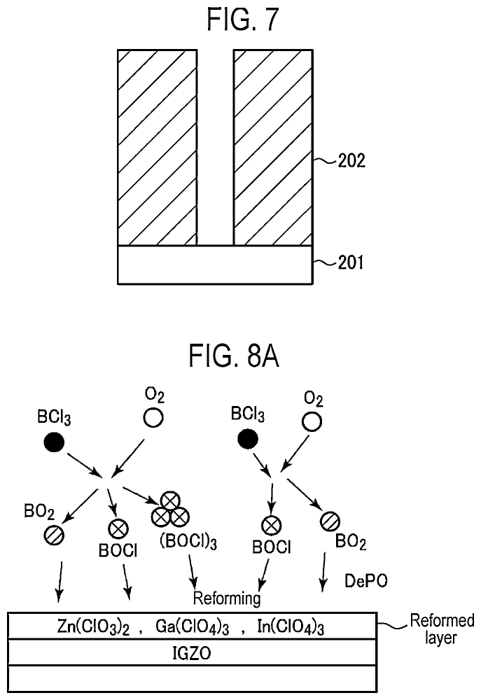

In step ST6, as illustrated in FIG. 7, the hard mask 203 is removed after etching the processing target 202. The removal of the hard mask 203 may be performed by a conventional wet cleaning using a chemical solution, or a reforming process and a pure water cleaning.

The wet cleaning is performed by selecting an appropriate chemical solution according to a material of the processing target 202, which is an underlayer of the hard mask 203. For example, if the processing target is Si, diluted hydrofluoric acid (DHF) (HF=about 1%) is suitable. Further, if the processing target is SiO₂, a mixed solution of phosphoric acid, nitric acid, and acetic acid (PAN) is suitable. The wet cleaning may be performed by immersing the substrate in a chemical solution stored in a container, or may be performed by applying the chemical solution onto the substrate.

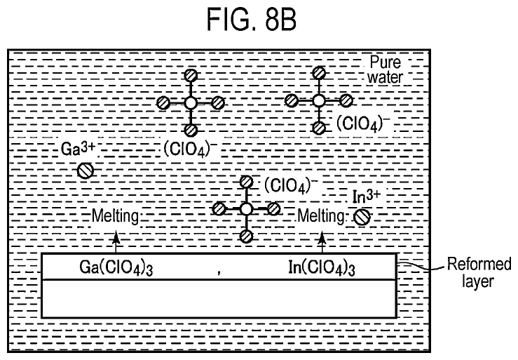

A method of removing the hard mask 203 by a reforming process and a pure water cleaning will be described with reference to FIGS. 8A and 8B. First, the reforming process is performed by introducing a mixed gas of BCl₃ and O₂ into an etching chamber where the processing target 202 has been etched. At this time, a reforming reaction occurs on a surface of the IGZO-based film constituting the hard mask 203 by the mixed gas of BCl₃ and O₂. For example, when the hard mask 203 is composed of an oxide of Ga, In, and Zn (IGZO), the oxide reacts with BCl₃ and O₂ on the surface, thereby being reformed into Zn(ClO₃)₂, Ga(ClO₄)₃, and In(ClO₄)₃, as illustrated in FIG. 8A. Among these, Zn(ClO₃)₂ volatilizes within the chamber since it is volatile. Further, Ga(ClO₄)₃ and In(ClO₄)₃ remain, but are water-soluble. Further, residues of Zn(ClO₃)₂ may also be removed with pure water. Therefore, as illustrated in FIG. 8B, after reforming process, the substrate is unloaded from the chamber and is subjected to pure water cleaning to remove the hard mask 203. This method is specific to the IGZO-based film and has the great effects of easily removing the hard mask 203 even when a chemical solution treatment is not preferred. Further, this method allows for the removal of a hard mask with an almost infinite selectivity with respect to an underlying processing target such as a SiO₂ film (SiO₂ is almost hardly etched).

The reforming process may be performed at 60 degrees C. or lower because a film-forming reaction may become predominant at high temperatures. Further, the reforming speed of reforming process depends on the composition ratio of BCl₃ and O₂, so that it is desirable to adjust the composition ratio of these to achieve a desired reforming speed.

Next, an example of a film forming apparatus for forming a hard mask according to an embodiment will be described in detail.

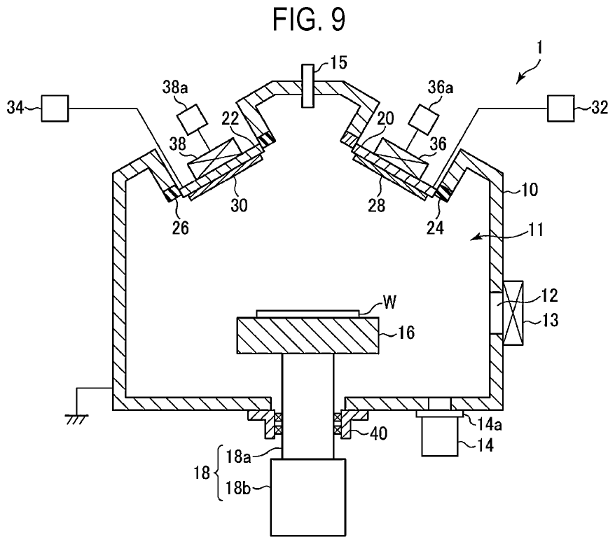

FIG. 9 is a cross-sectional view illustrating an example of a film forming apparatus used for forming a hard mask. The film forming apparatus 1 performs film formation by sputtering, which is a suitable film forming method described above. The film forming apparatus 1 includes a chamber 10 that has a substantially cylindrical shape and defines a processing space 11. The chamber 10 is made of a metal such as aluminum and is connected to a ground potential.

An exhaust port 14a is provided at the bottom of the chamber 10, and an exhaust device 14 is connected to the exhaust port 14a. The exhaust device 14 includes a pressure control valve and a vacuum pump. The exhaust device 14 is adapted to exhaust the interior of the chamber 10 and to control it to a desired vacuum degree. A sidewall of the chamber 10 is provided with a loading/unloading port 12 for loading or unloading a substrate W into or out of the chamber 10. The loading/unloading port 12 is opened or closed by a gate valve 13.

The top of the chamber 10 is provided with a gas introduction port 15 for introducing a gas into the processing space 11. The gas introduction port 15 is connected to a gas supply (not illustrated), and a gas is supplied from the gas supply to the processing space 11 through the gas introduction port 15. The supplied gas may be a noble gas such as Ar gas, or an inert gas such as N₂ gas.

A stage 16, on which the substrate W is placed, is provided within the chamber 10. The stage 16 may include an electrostatic chuck to electrostatically attract the substrate W. Further, the stage 16 may have a temperature regulator such as a heater or a coolant flow path. The stage 16 is connected to a drive mechanism 18. The drive mechanism 18 includes a support shaft 18a and a drive device 18b. The support shaft 18a extends from the rear center of the stage 16 to the outside through the bottom of the chamber 10. The drive device 18b is configured to rotate and lift the stage 16 via the support shaft 18a. A gap between the support shaft 18a and a bottom wall of the chamber 10 is sealed by a sealing member 40 such as a magnetic fluid seal.

The ceiling of the chamber 10 is conical and has an inclined surface, and metallic target holders 20 and 22 are installed to the inclined surface via respective insulating members 24 and 26 to face the stage 16. These target holders 20 and 22 are positioned to face each other and serve to hold targets 28 and 30, respectively. Power supplies 32 and 34 are electrically connected to the target holders 20 and 22, respectively. The power supplies 32 and 34 may be either direct current (DC) power supplies or radio frequency (RF) power supplies. The targets 28 and 30 include a part or the entirety of a material constituting a film to be formed. In addition, the number and arrangement of target holders are not limited to this example.

Magnets 36 and 38 are provided on the backside of the target holders 20 and 22, respectively. The magnets 36 and 38 serve to create a leakage magnetic field at the targets 28 and 30 to perform magnetron sputtering. The magnets 36 and 38 are configured to swing along the back of the target holders 20 and 22 by magnet drives 36a and 38a, respectively.

In the film forming apparatus 1 configured as above, the substrate W is loaded into the chamber 10 and is placed on the stage 16. Then, the drive mechanism 18 adjusts the vertical position of the stage 16 and rotates the stage 16.

Once the stage 16 is rotated, an inert gas such as Ar gas is supplied as a sputtering gas from the gas supply into the chamber 10, and the internal pressure of the chamber 10 is regulated to an evacuation state by the exhaust device 14. Then, power is supplied to the targets 28 and 30 from the power supplies 32 and 34, and the magnets 36 and 38 are driven by the magnet drives 36a and 38a. This concentrates plasma in the vicinity of the targets 28 and 30, causing positive ions in the plasma to collide with the targets 28 and 30. Thereby, the targets 28 and 30 release respective constituent materials thereof, causing the released materials to be deposited on the substrate W. This allows a film serving as a hard mask to be formed on the substrate W.

The composition of the targets 28 and 30 is adjusted so that the film formed on the substrate W is an IGZO-based film with a desired composition. The targets 28 and 30 may have the same composition or different compositions depending on the composition of a film to be formed. If they have the same composition, only one target may be used. If they have different compositions, the materials released from both the targets may be deposited on the substrate W to form a film with a desired composition.

Using the film forming apparatus 1 to form an IGZO-based film constituting a hard mask by sputtering facilitates the formation of an amorphous film with good shape retention during etching.

Next, an example of a plasma etching apparatus used for etching a hard mask and a processing target in the above-described substrate processing method will be described in detail.

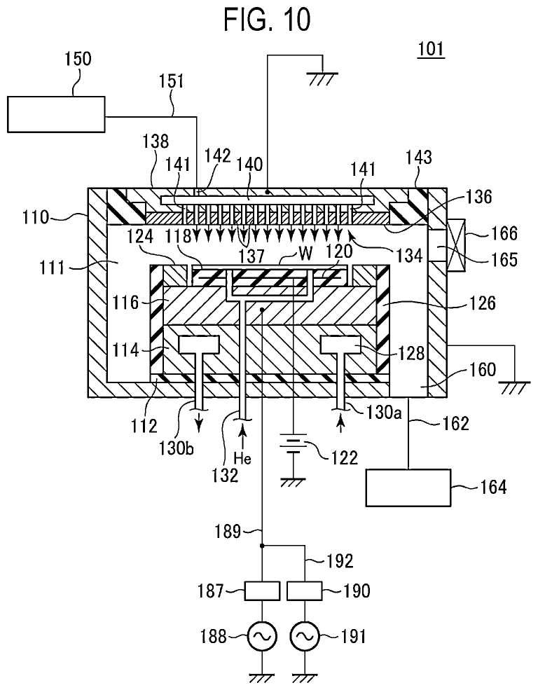

FIG. 10 is a cross-sectional view illustrating an example of a plasma etching apparatus. The plasma etching apparatus 101 is configured as a capacitively coupled plasma processing apparatus. The plasma etching apparatus 101 includes a chamber 110 that has a substantially cylindrical shape and defines a processing space 111. The chamber 110 is made of a metal such as aluminum with an anodized surface and is grounded for safety.

A cylindrical metallic support 114 is positioned at the bottom of the chamber 110 via an insulating plate 112, and a stage 116 made of a metal such as aluminum is provided on the support 114 to place the substrate W thereon. The stage 116 constitutes a lower electrode. The stage 116 includes an electrostatic chuck 118 at the top. The electrostatic chuck 118 has a configuration in which an electrode 120 is provided inside an insulator, and by applying a DC voltage from a DC power supply 122 for attraction purpose to the electrode 120, the substrate W is attracted and held by an electrostatic force such as Coulomb force.

A focus ring 124 made of a conductive material such as silicon is positioned around the electrostatic chuck 118. A cylindrical inner wall member 126 made of an insulator such as quartz is provided on side surfaces of the stage 116 and the support 114.

A coolant chamber 128 is provided inside the support 114, and a coolant such as cooling water is circulated from an external chiller unit (not illustrated) to the coolant chamber 128 through pipes 130a and 130b, thus controlling the processing temperature of the substrate W on the stage 116. Furthermore, a heat transfer gas such as He gas is supplied between the top of the electrostatic chuck 118 and the back of the substrate W through a gas supply line 132.

The stage 116, which serves as a lower electrode, is electrically connected to a first RF power supply 188 for plasma generation and a second RF power supply 191 for bias application. A matcher 187 is provided in a power supply line 189 that supplies power from the first RF power supply 188 to the stage 116. A power supply line 192 from the second RF power supply 191 is connected to the power supply line 189, and a matcher 190 is provided in the power supply line 192. The matchers 187 and 190 serve to match the load (plasma) impedance to the impedance on the first and second RF power supplies 188 and 191, respectively. The first RF power supply 188 for plasma generation has a higher frequency than the second RF power supply 191 for bias application.

An upper electrode 134 is provided above the stage 116, which serves as a lower electrode, to face the stage 116. Plasma is generated between the upper electrode 134 and the stage (lower electrode) 116.

The upper electrode 134 is supported at the top of the chamber 110 via an insulating shield member 143. The upper electrode 134 is composed of an electrode plate 136, which forms a surface facing the stage 116 and has a plurality of gas discharge holes 137, and a water-cooled-type electrode support 138, which detachably supports the electrode plate 136. The electrode plate 136 is made of a conductor such as silicon. The upper electrode 134 is connected to a ground potential. A gas diffusion chamber 140 is provided inside the electrode support 138, and a plurality of gas flow holes 141 extend downward from the gas diffusion chamber 140 and communicate with the gas discharge holes 137. A gas inlet 142 is formed in the electrode support 138 to introduce a process gas into the gas diffusion chamber 140. The gas inlet 142 is connected to a gas pipe 151 extending from a gas supply 150 to be described later. That is, the upper electrode 134 is configured as a shower head.

The gas supply 150 serves to supply an appropriate etching gas depending on a hard mask or a processing target. Further, the gas supply 150 also supplies an inert gas serving as a purge gas or a plasma generation gas. An etching gas such as a HBr gas, a Cl₂ gas, a CH₄ gas, a CH₃OH gas, and a BCl₃ gas may be suitably used when etching a hard mask. When using a HBr gas and a Cl₂ gas as the etching gas, it may be possible to use an O₂ gas, an Ar gas, and a N₂ gas as additive gases. When using a CH₄ gas, a CH₃OH gas, and a BCl₃, it may be possible to use a H₂ gas and a Cl₂ gas as additive gases. Further, as an etching gas for etching a processing target, a F-containing gas such as a CₓF_{y} gas, a CₓH_{y}F_{z} gas, or a SF₆ may be suitably used as described above. It is also permissible to add, e.g., an O₂ gas, a N₂ gas, and an Ar gas to the F-containing gas.

An exhaust port 160 is provided at the bottom of the chamber 110, and an exhaust device 164 is connected to the exhaust port 160 through an exhaust pipe 162. The exhaust device 164 includes a pressure control valve and a vacuum pump and exhausts the interior of the chamber 110 to control it to a desired vacuum degree. A sidewall of the chamber 110 is provided with a loading/unloading port 165 for loading or unloading the substrate W into or out of the chamber 110. The loading/unloading port 165 is opened or closed by a gate valve 166.

In the etching apparatus 101 configured above, the substrate W is loaded into the chamber 110 and is placed on the stage 116. Then, an inert gas is supplied into the chamber 110 from the gas supply 150, and the internal pressure of the chamber 110 is regulated to an depressurized state by the exhaust device 164. In this state, while supplying the etching gas from the gas supply 150, RF power for plasma generation is applied from the first RF power supply 188 to the stage 116, which serves as a lower electrode, and simultaneously, RF power for bias application is applied from the second RF power supply 191 to the stage 116. This creates a capacitively coupled plasma between the upper electrode 134 and the stage 116, which serves as a lower electrode, causing ions in the plasma to be drawn to the stage 116 to enable anisotropic etching of a hard mask or a processing target on the substrate W.

### EXPERIMENTAL EXAMPLES

Next, experimental examples will be described.

### Experimental Example 1

In Experimental Example 1, an experiment was conducted to etch a SiO₂ film used in, e.g., a DRAM forming step. Here, various IGZO-based films and conventional poly-Si and WSi films were used as a hard mask to etch the SiO₂ film, and the selectivity was obtained. The IGZO-based films used were an InGaZnO₄ film, In₂ZnO₄ film, Ga₂ZnO₄ film, In₂O₃ film, and ZnO film. The hard mask was formed by sputtering using the film forming apparatus of FIG. 9. Further, the etching of a processing target was performed using the apparatus of FIG. 10 with an etching gas such as a C₄F₈ gas, a C₄F₆ gas, and an O₂ gas.

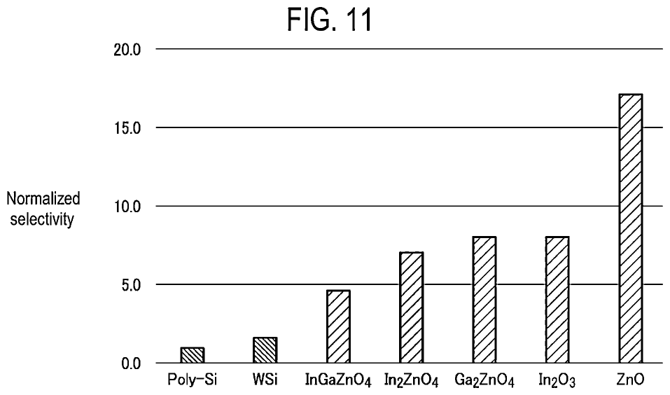

The results are illustrated in FIG. 11. FIG. 11 is a diagram illustrating selectivities of the hard masks with respect to SiO₂, which is a processing target. The selectivities were normalized with the selectivity of a poly-Si film set to 1. As illustrated in FIG. 11, when the IGZO-based films mentioned above were used as a hard mask for etching the SiO₂ film, all of them achieved higher selectivities compared to the conventional poly-Si and WSi films. That is, it was confirmed that using the IGZO-based films of the present embodiment as a hard mask for etching the SiO₂ film in the DRAM forming step provides a higher selectivity, thereby enabling the hard mask to be made thinner than the conventional methods. Further, among these IGZO-based films, the InGaZnO₄ film, In₂ZnO₄ film, Ga₂ZnO₄ film, and In₂O₃ film were amorphous state when they were formed, while the ZnO film was crystallized when it was formed. It was confirmed from this that the InGaZnO₄ film, In₂ZnO₄ film, Ga₂ZnO₄ film, and In₂O₃ film are more desirable in terms of shape retention.

### Experimental Example 2

In Experimental Example 2, an experiment was conducted to etch a stack of SiO₂/SiN films used in, e.g., a 3DNAND forming step. Here, various IGZO-based films and conventional amorphous carbon (ACL) and WSi films were used as a hard mask to etch the stack of SiO₂/SiN films, and the selectivity was determined. The IGZO-based films used were an InGaZnO₄ film, In₂ZnO₄ film, Ga₂ZnO₄ film, In₂O₃ film, and ZnO film. The hard mask was formed by sputtering using the film forming apparatus of FIG. 9. Further, the etching of a processing target film was performed using the apparatus of FIG. 10 with an etching gas such as a C₄F₈ gas, a C₄F₆ gas, an O₂ gas, and a CH₂F₂ gas.

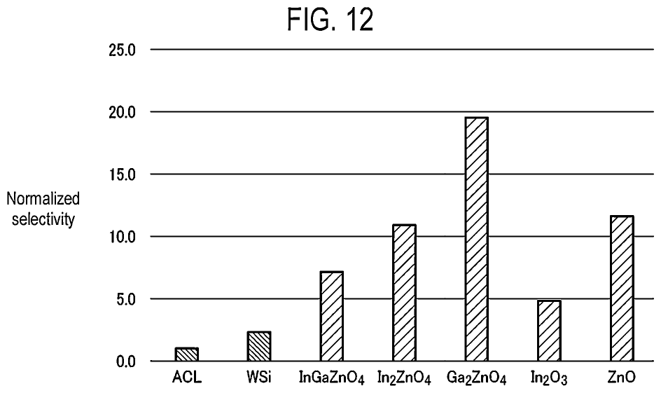

The results are illustrated in FIG. 12. FIG. 12 is a diagram illustrating the selectivities of the various hard masks with respect to the stack of SiO₂/SiN films, which is a processing target. The selectivities were normalized with the selectivity of an ACL film set to 1. As illustrated in FIG. 12, when the IGZO-based films mentioned above were used as a hard mask for etching the stack of SiO₂/SiN films, all of them achieved higher selectivities compared to the conventional ACL and WSi films. That is, it was confirmed that using the IGZO-based films of the present embodiment as a hard mask for etching the stack of SiO₂/SiN films in the 3DNAND forming step provides a higher selectivity, thereby enabling the hard mask to be thinner than the conventional methods. Further, similar to Experimental Example 1, among these IGZO-based films, the InGaZnO₄ film, In₂ZnO₄ film, Ga₂ZnO₄ film, and In₂O₃ film were amorphous state when they were formed, while the ZnO film was crystallized when it was formed. It was confirmed from this that the InGaZnO₄ film, In₂ZnO₄ film, Ga₂ZnO₄ film, and In₂O₃ film are more desirable in terms of shape retention.

### Other Applications

Although the embodiments have been described above, the embodiments disclosed herein should be considered to be exemplary and not restrictive in all respects. The above embodiments may be omitted, replaced, or modified in various ways without departing from the scope and spirit of the appended claims.

For example, in the above embodiments, the sputtering apparatus illustrated in FIG. 9 was exemplified as the film forming apparatus, but the film forming apparatus is not limited to this. It may also be a PVD apparatus with a different configuration, or any of film forming apparatuses using other film forming techniques such as CVD or ALD. Furthermore, it may be an apparatus that performs coating (spin coating).

Further, in the above embodiments, the capacitively coupled plasma processing apparatus illustrated in FIG. 10 was exemplified as the etching apparatus, but the etching apparatus is not limited to this. It may be a capacitively coupled plasma apparatus with a different configuration, or any of other apparatuses using plasma such as an inductively coupled plasma processing apparatus or a microwave plasma processing apparatus.

### EXPLANATION OF REFERENCE NUMERALS

1: film forming apparatus, 10: chamber, 16: stage, 32, 34: power supply, 28, 30: target, 101: plasma etching apparatus, 110: chamber, 116: stage (lower electrode), 134: upper electrode, 150: gas supply, 188: first radio frequency power supply, 191: second radio frequency power supply, 200: substrate, 201: base, 202: processing target, 203: hard mask, W: substrate

1. A hard mask used for etching a processing target, the hard mask comprising an oxide containing one or more of gallium, indium, and zinc.

2. The hard mask of claim 1, wherein the processing target is a silicon-containing film.

3. The hard mask of claim 1, wherein the etching the processing target is performed using a fluorine-containing gas.

4. The hard mask of claim 1, wherein the oxide containing one or more of gallium, indium, and zinc is amorphous.

5. The hard mask of claim 4, wherein the oxide containing one or more of gallium, indium, and zinc is any of InGaZnO₄, In₂ZnO₄, Ga₂ZnO₄, and In₂O₃.

6. A substrate processing method comprising:
preparing a substrate having a processing target;
forming a hard mask on the processing target, the hard mask including an oxide that contains one or more of gallium, indium, and zinc;
etching the hard mask into a desired pattern; and
etching the processing target using the hard mask as a mask.

7. The substrate processing method of claim 6, wherein the processing target is a silicon-containing film.

8. The substrate processing method of claim 6, wherein the etching the processing target is performed using a fluorine-containing gas.

9. The substrate processing method of claim 6, wherein the oxide that contains one or more of gallium, indium, and zinc is amorphous.

10. The substrate processing method of claim 9, wherein the oxide that contains one or more of gallium, indium, and zinc is any of InGaZnO₄, In₂ZnO₄, Ga₂ZnO₄, and In₂O₃.

11. The substrate processing method of claim 6, wherein the forming the hard mask is performed by plasma vapor deposition (PVD).

12. The substrate processing method of claim 6, wherein the etching the hard mask into the desired pattern and the etching the processing target are performed by anisotropic etching using plasma.

13. The substrate processing method of claim 6, wherein the etching the hard mask into the desired pattern includes patterning by photolithography, followed by etching the hard mask using a pattern formed by the patterning.

14. The substrate processing method of claim 6, further comprising, after the etching the processing target, removing the hard mask by supplying a mixed gas of BCl₃ and O₂ to the hard mask to reform the hard mask and then performing pure water cleaning.

15. A method of removing a hard mask after etching a processing target using the hard mask as a mask, the hard mask including an oxide that contains one or more of gallium, indium, and zinc, the method comprising:
supplying a mixed gas of BCl₃ and O₂ to the hard mask to reform the hard mask; and
performing pure water cleaning after reforming the hard mask to remove the hard mask.

16. The substrate processing method of claim 7, wherein the forming the hard mask is performed by plasma vapor deposition (PVD).
